(19) United States
(12) Patent Application Publication
(10) Pub. No.: US 2006/0228853 A1
(43) Pub. Date: Oct. 12, 2006

(54) Memory devices including spacers on sidewalls of memory storage elements and related methods

(76) Inventors: Won-Cheol Jeong, Seoul (KR); Se-Ho Lee, Seoul (KR); Kyung-Chang Ryoo, Seongnam-si (KR); Jae-Hyun Park, Yongin-si (KR)

Correspondence Address: MYERS BIGEL SIBLEY & SAJOVEC, PO BOX 37428, RALEIGH, NC, 27627, US

(21) Appl. No.: 11/388,111

(22) Filed: Mar. 23, 2006

(30) Foreign Application Priority Data
Mar. 28, 2005 (KR) 10-2005-0025369

(51) Int. Cl. H01L 21/8244; H01L 21/8234

(52) U.S. Cl. 438/238

(57) ABSTRACT

A method of forming a memory device may include forming an insulating layer on a substrate, and forming a first electrode through at least a portion of the insulating layer. A memory storage element may be formed on the first electrode so that the first electrode is between the memory storage element and the substrate, and a second electrode may be formed on the memory storage element so that the memory storage element is between the first and second electrodes. After forming the memory storage element and after forming the second electrode, insulating spacers may be formed on sidewalls of the memory storage element. After forming the insulating spacers, an interconnection line may be formed on the second electrode, on the insulating spacers, and on the insulating layer beyond the insulating spacers. Related memory devices are also discussed.

### RELATED PATENT APPLICATION

This application claims the benefit of priority from Korean Patent Application No. 10-2005-0025369, filed on Mar. 28, 2005, in the Korean Intellectual Property Office, the disclosure of which is incorporated herein in its entirety by reference.

### FIELD OF THE INVENTION

The present invention relates to electronics, and more particularly, to memory devices and related methods of fabrication.

### BACKGROUND

Non-volatile memory devices are capable of maintaining stored information without periodic refresh operations and/or through interruption of power. This can be achieved using a resistance device.

For example, a phase change random access memory (PRAM) stores data using a change in resistance according to a phase transformation of a phase change layer between a crystalline state and an amorphous state. A magnetic random access memory (MRAM) uses a ferromagnetic thin film structure such as tunneling magnetoresistance (TMR) element and/or a giant magnetoresistance (GMR) element, and/or a structure including multi magnetic layers as an information storage element. As an example, an MRAM using TMR elements uses a magnetic tunnel junction (MTJ) structure as the information storage element. In this case, the MRAM stores information using a difference in magnetic resistance according to the relative orientation of magnetization at a first ferromagnetic layer and a second ferromagnetic layer of the MTJ structure.

For memory devices which use a resistance element like an MRAM or a PRAM, information stored in the resistance element may be read out by passing a current through the resistance element to measure its resistance level. These, memory devices may thus include a contact structure used to pass current through top and bottom parts of information storage elements. A bottom electrode contact (BEC) and a top electrode contact (TEC) are examples of the contact structure.

As semiconductor devices have become more highly integrated, cell sizes of memory devices have been scaled down, reducing the size of the contacts. However, sufficiently small contacts may be difficult to form, especially the TECs. For example, at the bottom part of the TEC, a resistance element such as an MTJ structure or a phase change layer like a (Ge,Sb,Te) layer (which is often abbreviated as GST) may be allocated. Thus, when forming the TEC or an alternative structure, it may be difficult to protect the resistance element from damage.

### SUMMARY

According to some embodiments of the present invention, a method of forming a memory device may include forming an insulating layer on a substrate, and forming a first electrode through at least a portion of the insulating layer. A memory storage element may be formed on the first electrode so that the first electrode is between the memory storage element and the substrate. A second electrode may be formed on the memory storage element so that the memory storage element is between the first and second electrodes. After forming the memory storage element and after forming the second electrode, insulating spacers may be formed on sidewalls of the memory storage element, and after forming the insulating spacers, an interconnection line may be formed on the second electrode, on the insulating spacers, and on the insulating layer beyond the insulating spacers.

According to some other embodiments of the present invention, a memory device may include an insulating layer on a substrate, a first electrode through at least a portion of the insulating layer, and a memory storage element on the first electrode so that the first electrode is between the memory storage element and the substrate. A second electrode may be on the memory storage element so that the memory storage element is between the first and second electrodes, and insulating spacers may be on sidewalls of the memory storage element. The memory device may also include an interconnection line on the second electrode, on the insulating spacers, and on the insulating layer beyond the insulating spacers so that the insulating spacers are between the interconnection line and sidewalls of the memory storage element.

According to some embodiments of the present invention, a memory device may be provided without a top electrode contact, and related methods of forming such a memory device may also be provided.

According to some embodiments of the present invention, a method for fabricating a memory device using a resistance device as a data storage element may include forming a first insulation layer on a substrate, forming a bottom electrode contact passing through the first insulation layer, and forming a memory pattern and a top electrode pattern aligned with the memory pattern on the first insulation layer. The memory pattern may contact the bottom electrode contact in a vertical alignment with respect to the bottom electrode contact to shield the bottom electrode contact. Insulation spacers may be formed to isolate the memory pattern by shielding at least lateral sides of the memory pattern and an interconnection line may be formed over the insulation spacers, in direct contact with the top electrode pattern.

In the case of a phase change random access memory (PRAM), the memory pattern may be formed in a patterned phase change layer. The patterned phase change layer may contact the bottom electrode contact and may be in a vertical alignment with respect to the bottom electrode contact to shield the bottom electrode contact. The patterned phase change layer may also have a resistance which changes according to a phase transformation.

In the case of a magnetic random access memory (MRAM), the memory pattern may include a magnetic tunnel junction (MTJ) structure. The MTS structure may contact the bottom electrode contact and may be in a vertical alignment with respect to the bottom electrode contact to shield the bottom electrode contact. The MTJ structure may have a resistance which changes according to an arrangement of magnetic spin directions of magnetic layers.

Also, forming the insulation spacers may include forming a second insulation layer including a silicon oxide layer covering the memory pattern and the top electrode pattern. In addition, a dry etching process may be performed on the second insulation layer to form the insulation spacers covering the lateral sides of the memory pattern and exposing the upper surface of the top electrode pattern. At this time, the silicon oxide layer may be obtained by depositing a plasma enhanced tetraethylorthosilicate silicon oxide.

According to other embodiments of the present invention, a memory device using a resistance device as a data storage element may be provided based on the aforementioned memory device fabrication method. The memory device may also include an interconnection line in direct contact with the top electrode pattern. The insulation spacers may be formed in a stack structure in which first spacers and second spacers are stacked.

### BRIEF DESCRIPTION OF THE DRAWINGS

FIGS. 1 through 6 are cross-sectional views illustrating memory devices and methods for fabricating the same in accordance with first embodiments of the present invention.

FIGS. 7 and 8 are cross-sectional views illustrating examples of resistance elements of memory devices in accordance with the first embodiments of the present invention.

FIGS. 9 through 11 are cross-sectional views illustrating memory devices and methods for fabricating the same in accordance with second embodiments of the present invention.

### DETAILED DESCRIPTION

The present invention is described more fully hereinafter with reference to the accompanying drawings, in which embodiments of the present invention are shown. This invention may, however, be embodied in many different forms and should not be construed as limited to the embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity. Like numbers refer to like elements throughout.

It will be understood that when an element or layer is referred to as being “on”, “connected to” or “coupled to” another element or layer, it can be directly on, connected or coupled to the other element, or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly. Also, as used herein, “lateral” refers to a direction that is substantially orthogonal to a vertical direction.

The terminology used herein is for the purpose of describing particular embodiments only, and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Examples of embodiments of the present invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. Accordingly, these terms can include equivalent terms that are created after such time. It will be further understood that terms, such as those defined in commonly used dictionaries, should be interpreted as having a meaning that is consistent with their meaning in the present specification and in the context of the relevant art, and will not be interpreted in an idealized or overly formal sense unless expressly so defined herein. All publications, patent applications, patents, and other references mentioned herein are incorporated by reference in their entirety.

According to embodiments of the present invention, a memory device can be constructed using a resistance element such as a magnetic random access memory (MRAM) element or a phase change random access memory (PRAM) element, without a top electrode contact for current through the resistance element when reading information. To increase the integration of memory devices using such resistance elements, the top electrode contact may be eliminated. Thus, it may be possible to provide smaller, more highly integrated memory devices.

To eliminate top electrode contacts in memory devices according to embodiments of the present invention, the resistance element (such as a magnetic tunnel junction MTJ structure and/or a (Ge, Sb, Te) (GST) layer) may be patterned, and then, an insulation layer may be formed directly covering the pattern of the resistance element. Subsequently, the insulation layer may be etched to form insulation spacers on sidewalls of the pattern of the resistance element. The insulation spacers may isolate the resistance element and simultaneously expose an upper part of its pattern. Afterwards, an interconnection line may be formed to contact an exposed upper part of the pattern of the resistance element and create an electrical connection. At this time, a dry etching process (such as an etch-back process) may be used to form the insulation spacers.

Through the above sequential processes, the resistance element of the memory device may make a direct electrical connection with the interconnection line, so that a separate top electrode contact may not be needed.

In a structure where an interconnection line is directly connected to an upper part of a resistance element without using a top electrode contact, a chemical mechanical polishing (CMP) process can be used to polish the insulation layer covering the pattern of the resistance element to expose the upper surface of the pattern of the resistance element.

However, the CMP process may result in physical stress at the resistance element which may result in damage to the resistance element of the memory device. The CMP process may thus damage the resistance element and/or other elements.

Instead of using a CMP process, some embodiments of the present invention may etch the insulation layer to form the insulation spacers to thereby reduce damage that may result from CMP. Also, an interconnection line (such as a metal line) may make direct contact with an upper part of the pattern of the resistance element encompassed by the insulation spacers. Thus, it may be possible to provide a simplified process and more effectively reduce damage to the resistance element during subsequent processes.

An MTJ structure and/or GST layer having variable resistance may be sensitive to thermal processing. If a CMP process is performed, a layer accompanying a thermal process performed at high temperature may need to be formed. A silicon nitride layer may be one example of such a layer. This thermal process, however, may degrade characteristics of the MTJ structure and/or the GST layer. According to some embodiments of the present invention, the insulation spacers may be formed of a material (such as silicon oxide) that can be formed even at a low temperature. Thus, it may be possible to reduce damage of the MTJ or GST structure resulting from the thermal process.

A thermal process at a temperature greater than approximately 300° C. can damage an MTJ structure. Also, a thermal process at a temperature greater than approximately 380° C. can damage a GST layer. For this reason, the insulation spacers may include a silicon oxide layer that can be formed at a lower temperature than those mentioned above. For example, the insulation layer can be formed using a plasma deposition method (such as a plasma enhanced tetraethylorthosilicate PE-TEOS deposition) so that damage to the MTJ and/or GST structure caused by the thermal process can be reduced.

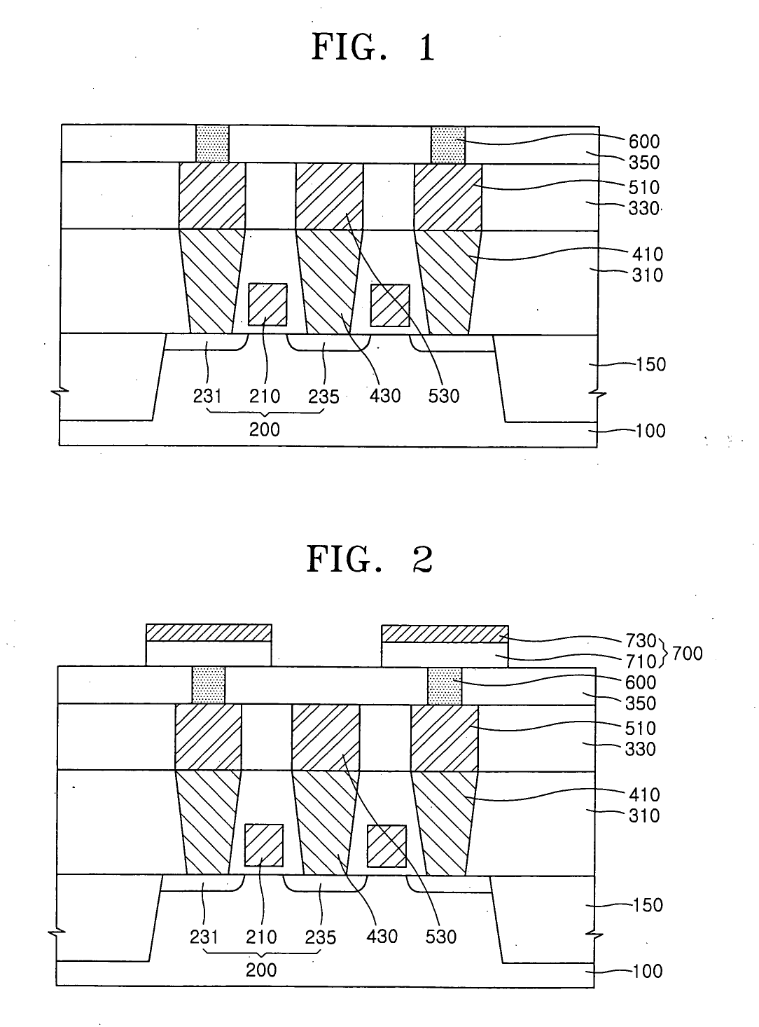

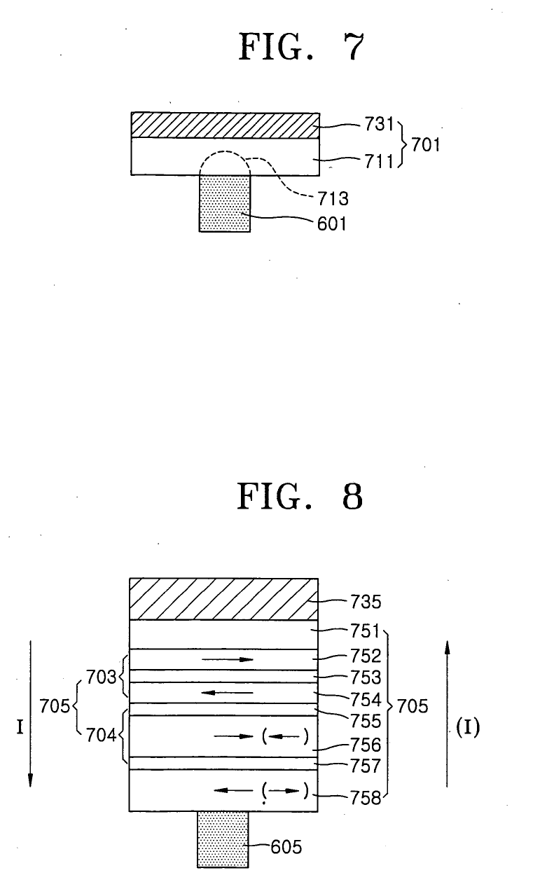

FIGS. 1 through 6 are cross-sectional views illustrating memory devices and methods for fabricating the same in accordance with first embodiments of the present invention. FIGS. 7 and 8 are cross-sectional views illustrating examples of resistance elements of memory devices in accordance with first embodiments of the present invention.

Referring to FIG. 1, a memory device may include a plurality of bottom electrodes (BECs) 600 (also referred to as bottom electrode contacts or BECs) electrically connected to a semiconductor substrate 100. The bottom electrodes 600 can be formed to make individual electrical connections to transistor devices 200 formed on the substrate 100. Prior to forming the lower electrodes 600, device isolation regions (150 including an insulating material), can be formed on the substrate 100 to define “active region(s)”, and then the transistors 200 may be formed in the active region of the substrate 100. To form the individual transistors 200, a gate(s) 210 (including a gate dielectric layer) may be formed on the substrate 100, and ion implantation may be used to form a source region(s) 231 and a drain region(s) 235 adjacent to the gate 210.

After forming the transistor device(s) 200, a first insulation layer 310 is formed to cover the transistor devices 200 and the device isolation regions 150. Then, a plurality of first lower contacts 410 may be electrically connected to the corresponding source regions 231, and a second lower contact(s) 430 may be electrically connected to the drain region(s) 235. At this time, the first lower contacts 410 and the second lower contact 430 pass through the first insulation layer 310. Afterwards, a plurality of upper contacts 510 are formed, insulated and isolated by a second insulation layer 330 formed on the first insulation layer 310, and the upper contacts 510 may be electrically connected to respective first lower contacts 410. In addition, a first bit line 530 may be formed, electrically insulated from the upper contacts 510 by the second insulation layer 330 but electrically connected to the second lower contact 430.

Next, a third insulation layer 350 may be formed on the bit line 530 and the upper contacts 510. As the bottom electrodes 600 are aligned with the upper contacts 510 when passing through the third insulation layer 350, the bottom electrodes 600 are electrically connected to the respective upper contacts 510. More particularly, the third insulation layer 350 may be selectively etched to form a plurality of contact holes each exposing an upper surface portion of one of the upper contacts 510. Then, a conductive material may be filled into the contact holes and subjected to an etch-back process and/or a chemical mechanical polishing (CMP) process, thereby forming the bottom electrodes 600. At this time, the bottom electrodes 600 can include sequentially stacked layers of titanium nitride (TiN) and titanium (Ti).

FIG. 2 shows patterns of resistance elements used to store information using a change in resistance. Formation of memory patterns 710 is discussed with respect to in FIG. 2.

A memory layer covering the exposed bottom electrodes 600 may be formed on the third insulation layer 350 and then patterned to provide the memory pattern(s) 710. At this time, a top electrode layer can be formed on the memory layer, and then a photolithography process can be used to sequentially pattern the top electrode layer and the memory layer, to form the memory pattern 710 and top electrode 730 aligned with the memory pattern 710.

The memory pattern(s) 710 and the top electrode(s) 730 may together provide an information storage element(s) 700, which stores information using change(s) in resistance of the memory pattern 710. For example, each memory pattern 710 may include a phase change layer which varies its resistance depending on whether it is in a crystalline or amorphous state, or a magnetic tunnel junction (MTJ) structure which varies its resistance depending on a magnetic spin direction. Therefore, the information storage element 700 can be viewed as a resistance element providing a variable resistance.

When each of the memory pattern(s) 710 includes a phase change layer, and the memory device is configured as a phase change memory device, the memory pattern 710 can be configured as a phase change memory element 701, as shown in FIG. 7. Referring to FIG. 7, a patterned phase change layer 711 may be formed as the memory pattern 710 shown in FIG. 2 in contact with a bottom electrode 601, and a top electrode 731 may be formed on the patterned phase change-layer 711.

The patterned phase change layer 711 changes its resistance as its crystal structure changes due to Joule heating as current flows between the bottom electrode 601 and the top electrode 731. Once an amorphous portion 713 is formed within the patterned phase change layer 711 through Joule heating and subsequent cooling, the resistance of the patterned phase change layer 711 may be different than the resistance in the initial crystalline state. On the basis of this difference in resistance, information may be written and read.

To speed up write and erase operations used to store information, a size of the bottom electrode 601 may be reduced. A writing and/or erasing period may be dependent on a volume of the amorphous portion 713, which may depend on a contact area between the bottom electrode 601 and the patterned phase change layer 711. As a result, reducing an area of a contact between the bottom electrode 601 and the patterned phase change layer 711 may be achieved by reducing a size of the bottom electrode 601.

If the memory pattern 710 shown in FIG. 2 is provided as a MTJ so that the memory device is a magnetic memory device, as shown in FIG. 8, the individual memory pattern 710 may include a MTJ structure 705. Although the MTJ structure 705 can take various forms, the MTJ structure 705 may be include a stack of a plurality of magnetic layers alternating with insulating non-magnetic layers. Such an MRAM may store information using a change in resistance according to the magnetic spin orientations of the magnetic layers.

With reference to FIG. 8, the MTJ structure 705 may be provided as the memory pattern 710 shown in FIG. 2, in contact with a bottom electrode 605, and a top electrode 735 can be formed on the MTJ structure 705. The MTJ structure 705 may include an anchor or pinned layer 703 (hereinafter referred to as the anchor layer), a free layer 704, and an insulating non-magnetic layer 755 formed between the anchor layer 703 and the free layer 704. The MTJ structure 705 may be located between the bottom electrode 605 and the top electrode 735. The bottom electrode contact 605 may be electrically connected to the selected transistor device 200 shown in FIG. 2

As illustrated in FIG. 8, the anchor layer 703 may have a fixed magnetization orientation, and the free layer 704 may have a magnetization orientation that may change responsive to magnetic spin injection induced by current flowing through the MTJ structure 705. Each of the anchor layer 703 and the free layer 704 can include a ferromagnetic layer. For example, the anchor layer 703 can include a ferro-cobalt (CoFe) layer, and the free layer 704 can include a ferro-nickel (NiFe) layer.

In the anchor layer 703, an anti-ferromagnetic exchange layer 751 may fix a magnetization orientation of the anchor layer 703. The anti-ferromagnetic exchange layer 751 may include an iridium manganese (IrMn) layer. The insulating non-magnetic layer 755 may include an aluminium oxide (Al₂O₃) layer.

Depending on whether there is a parallel or anti-parallel magnetization orientation between magnetizations of the anchor layer 703 and the free layer 704, the MTJ structure 705 exhibits a different resistance, thereby allowing the reading and writing of information. In the case of a parallel magnetization orientation, the MTJ structure 705 may provide a relatively low resistance. In the case of an anti-parallel magnetization orientation, the MTJ structure 705 may provide a relatively a high resistance.

Although the anchor layer 703 and the free layer 704 may include a single magnetic layer, as shown in FIG. 8, these layers can alternatively be formed in a stack structure with stacked magnetic layers having parallel magnetization orientations in opposite directions. An anti-ferromagnetic coupling structure is an example of such a stack structure.

Also, the anchor layer 703 of the anti-ferromagnetic coupling structure can be formed so that a first conductive non-magnetic layer 753 is formed between a first magnetic layer 752 and a second magnetic layer 754. The first magnetic layer 752 and the second magnetic layer 754 can be formed with substantially the same relatively thin thickness. The free layer 704 of the anti-ferromagnetic coupling structure can be formed so that a second conducive non-magnetic layer 757 is formed between a third magnetic layer 756 and a fourth magnetic layer 758. The third magnetic layer 756 and the fourth magnetic layer 758 can be formed with substantially the same relatively thick thickness.

When the current I passing through the MTJ structure 705 flows from the top electrode 735 to the bottom electrode 605, as shown in FIG. 8, the magnetization orientation of the first, second, third and fourth magnetic layers 752, 754, 756 and 758 can be expressed by primary arrows shown in FIG. 8. If the current I flows in the opposite direction, as denoted by (I) in FIG. 8, the magnetization orientations of the individual magnetic layers, specifically, the third magnetic layer 756 and the fourth magnetic layer 758, can be changed to opposite directions in the free layer 704. These changed magnetic orientations are expressed by secondary arrows in parentheses. Thus, as the magnetization orientation of the second magnetic layer 754 (which is one element of the anchor layer 703) changes relative to that of the third magnetic layer 756 (which is one element of the free layer 704) so that relative magnetic spin directions of the second magnetic layer 754 and the third magnetic layer 756 change, the a resistance of MTJ structure 705 may change. An order of stacking of the anchor layer 703 and the free layer 704 can also be changed to the opposite of that shown in FIG. 8, according to embodiments of the present invention.

Accordingly, to store information, the memory pattern 710 shown in FIG. 2 may provide a variable resistance device using an MTJ structure 705 as shown, for example, in FIG. 8 or a phase change memory element 701 as shown, for example, in FIG. 7.

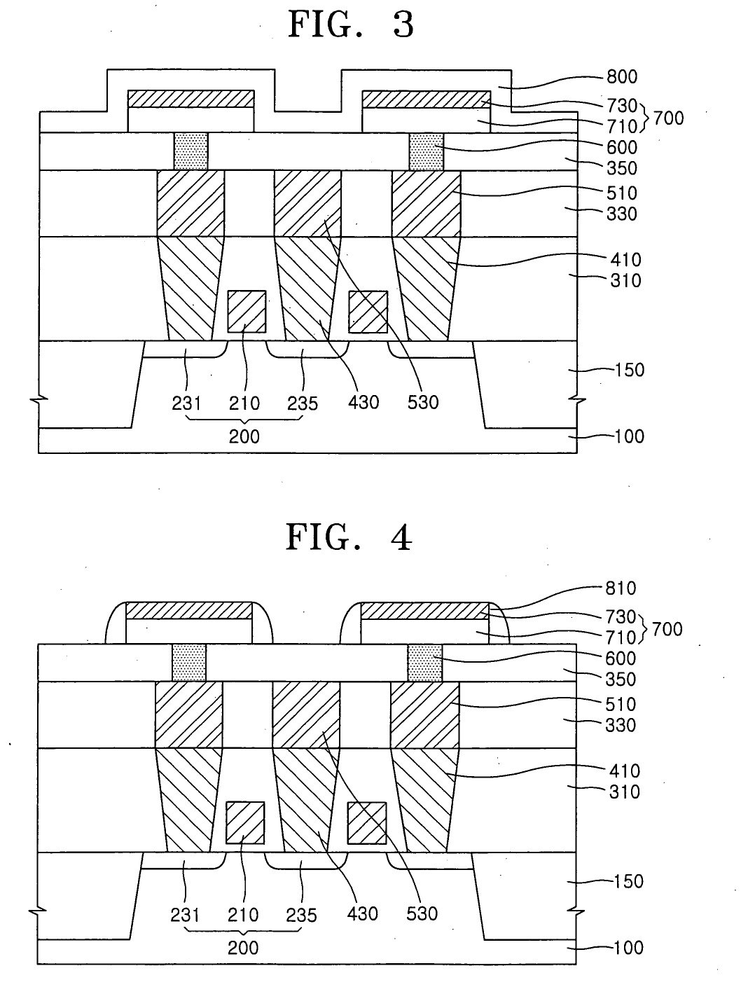

Referring to FIG. 3, after the memory patterns 710 or/and the top electrodes 730 shown in FIG. 2 are patterned, a fourth relatively thin insulation layer 800 may be formed thereon, covering the storage information elements 700. The fourth insulation layer 800 may be used to form insulation spacers, covering lateral sidewalls of the storage information element 700, more particularly, the memory patterns 710.

Characteristics of a material(s) used to form the memory patterns 710 (for example, the patterned phase change layer 711 shown in FIG. 7 based on GST or the MTJ structure 705 shown in FIG. 8) may be degraded as a result of a high temperature thermal process. The fourth insulation layer 800 used to form the insulation spacers may be a relatively thin insulation film capable of being formed at a low temperature to reduce damage to the memory patterns. For example, the fourth insulation layer 800 may include a silicon oxide layer formed using a plasma enhanced tetraethylorthosilicate (PE-TEOS) formation process.

If the memory pattern 710 is for a MRAM, material characteristics of the MTJ structure 705 shown in FIG. 8 may be degraded by a thermal process at more than approximately 300° C. Thus, the silicon oxide layer may be formed at a temperature lower than approximately 800° C. If the memory pattern 710 is for a phase change RAM (PRAM), material characteristics of the patterned phase change layer 711 shown in FIG. 7 may be degraded by a thermal process at more than approximately 380° C. Thus, the silicon oxide layer may be formed at a temperature less than approximately 380° C.

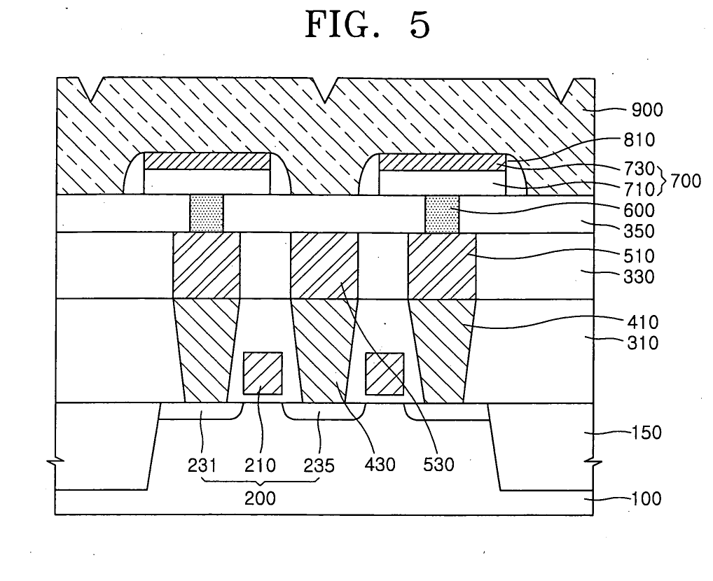

Referring to FIG. 4, the fourth insulation layer 800 may be etched to form insulation spacers 810 covering at least lateral sidewalls of the memory pattern 710 while exposing upper surfaces of the top electrodes 730. For example, an etch-back process (which may be a type of dry etching process) may be used to etch the fourth insulation layer 800 to form the insulation spacers 810.

Because the memory patterns 710 cover the entire surfaces of respective bottom electrodes 600 and the bottom electrodes 600 are in axial alignment with the respective memory patterns 710, the insulation spacers 810 that shield the lateral sidewalls of the memory patterns 710 may also insulate the bottom electrodes 600 from each other. Therefore, even if the upper surface of the third insulation layer 350 is exposed during the dry etching process for forming the insulation spacers 810, the bottom electrodes 600 passing through the third insulation layer 350 may not be exposed.

Referring to FIG. 5, an interconnection line 900, electrically connected to the exposed top electrodes 730, may be formed. The interconnection line 900 may be used as another bit line. Because the interconnection line 900 is formed to make direct contact with the top electrodes 730, a separate top electrode contact (TEC) may not be necessary between the interconnection line 900 and the corresponding top electrode 730. Even in the absence of a separate top electrode contact, the insulating spacers 810 may insulate lateral sidewalls of the memory patterns 710 from the interconnection line 900.

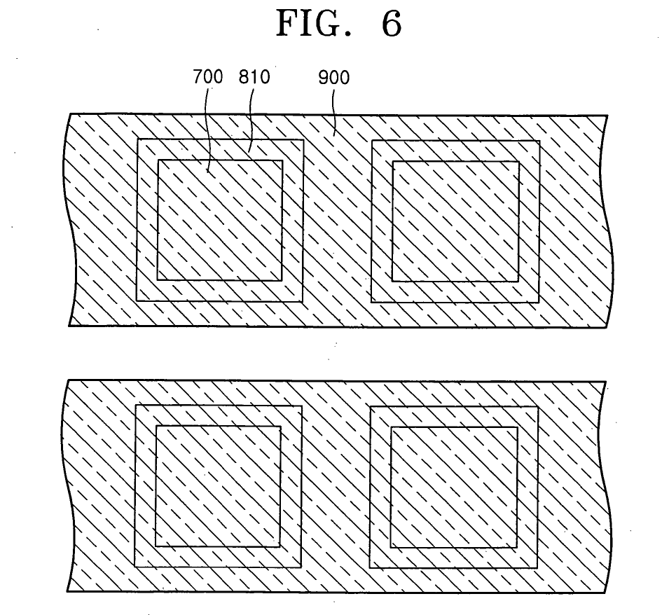

If the interconnection line 900 includes a metal layer, the interconnection line 900 may be patterned. As shown in FIG. 6, for example, the metal layer may be patterned such that a plurality of information storage elements 700 arranged in a same direction may be in contact with a same interconnection line 900.

As shown in FIG. 5, the insulating spacers 810 covering sidewalls of the memory patterns 710 may be formed using a single application of a spacer formation process. That is, the fourth insulation layer 800 may be formed over the information storage elements 700, and then subjected to a dry etching process. To provide a more stable insulation of lateral sidewalls of the memory patterns 710, the above spacer formation process can be applied two or more times.

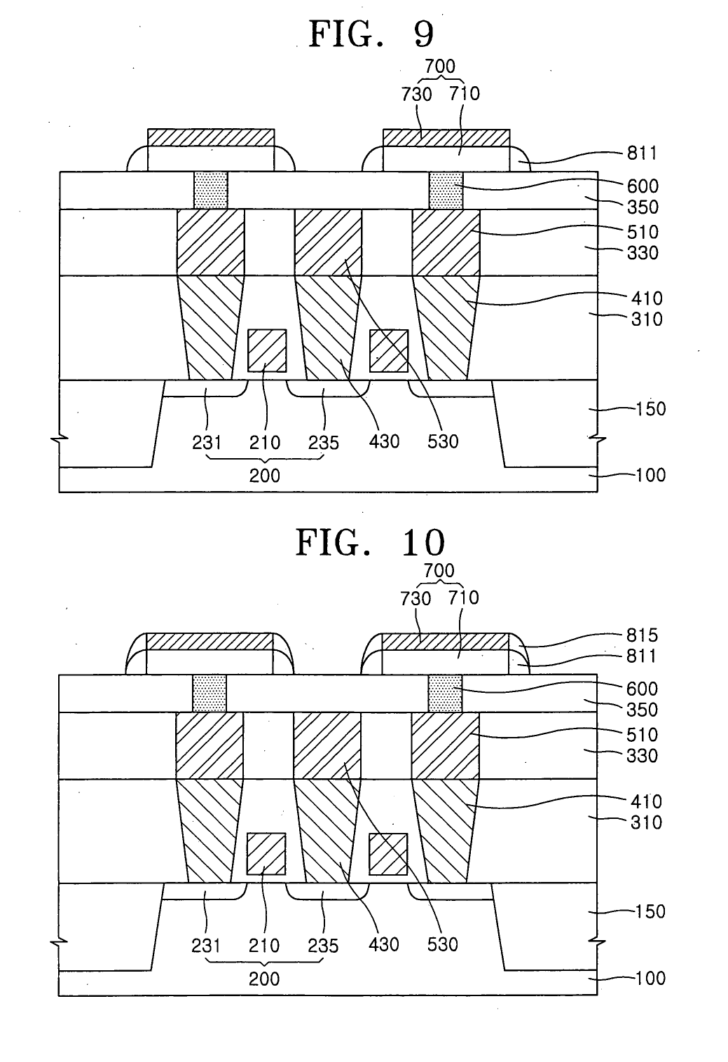

FIGS. 9 through 11 are cross-sectional views illustrating memory devices and methods for fabricating the same in accordance second embodiments of the present invention. In FIGS. 9-11 the same reference numerals are used for elements common to FIGS. 1 through 8.

Referring to FIG. 9, patterns of resistance elements that store information using changes in resistance (i.e., memory patterns 710) and top electrodes 730 may be formed on bottom electrodes 600. Then, a relatively thin fifth insulation layer may be formed covering information storage elements 700 including the memory patterns 710 or/and the top electrodes 730. Then, an etching process to form a spacer may be performed on the fifth insulation layer to provide first spacers 811 to insulate the information storage elements 700, and more particularly to insulate lateral sidewalls of the memory patterns 710.

During the etching process used to form the first spacers 811, if the fifth insulation layer is over-etched, the first spacers 811 may not be sufficient to cover the lateral sidewalls of the memory pattern 710. Additional spacers can thus be formed on the first spacers 811.

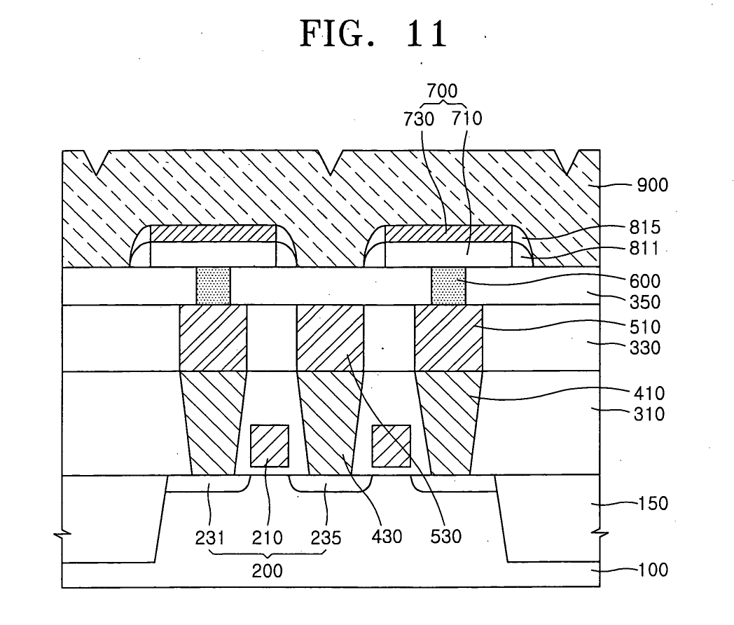

Referring to FIG. 10, formation of the additional spacers will be described. After forming the first spacers 811, a sixth insulating layer may be formed on the first spacers 811 and the top electrodes 730, and the sixth insulating layer may then be subjected to an etch-back process. As a result of the etch-back process, second spacers 815 may be formed on the first spacers 811. By providing the second spacers 815, more stable isolation of lateral sidewalls of the memory patterns 710 may be provided.

By forming the spacers in a dual structure including the first spacers 811 and the second spacers 815, the lateral sidewalls of the memory patterns 710 may be more stably isolated. That is, both the fifth insulating layer used to form the first spacers 811 and the sixth insulation layer used to form the second spacers 815 can be formed more thinly than the fourth insulating layer 800 used to form the insulating spacers 810 of the first embodiments.

Although the first spacers 811 and the second spacers 815 may be formed using two repetitive processes as shown in FIG. 10, these processes can be repeated additional times according to embodiments of the present invention. The first spacers 811 and the second spacers 815 may be formed using a silicon oxide layer which can be formed at a relatively low temperature.

Referring to FIG. 11, an interconnection line 900 may be formed, electrically connected to exposed surfaces of the top electrodes 730. The interconnection line 900 may be used as another bit line. Because the interconnection line 900 is formed to make direct contact with the top electrodes 730, a separate top electrode contact (TEC) between the interconnection line 900 and the selected top electrode 730 may be omitted. Even in the absence of a separate top electrode contact, the dual spacer structure including the first spacers 811 and the second spacers 815 may insulate lateral sidewalls of the memory patterns 710 from the interconnection line 900.

According to first and second embodiments of the present invention discussed above, a metal interconnection line can make a direct electrical connection with memory elements without a separate top electrode contact in a memory device such as an MRAM and/or a PRAM. Because insulation spacers are formed on each lateral sidewall of a memory pattern configured in a phase change layer or MTJ structure, the lateral sidewalls of the memory pattern may be isolated or insulated from a metal interconnection line above the memory pattern. The metal interconnection can thus make an electrical connection through direct contact with the top electrode. For this reason, a separate top electrode contact (which is typically provided in a conventional memory device) may be omitted.

Elimination of a separate top electrode contact may allow increased integration of memory devices such as MRAMs and PRAMs. Furthermore, by forming spacers, it is not necessary to perform a chemical mechanical polishing (CMP) process that may otherwise damage the memory pattern. Accordingly, degradation of the memory pattern due to CMP processes can be reduced so that the memory pattern may provide more stable resistance changes.

While the present invention has been particularly shown and described with reference to embodiments thereof, it will be understood by those of ordinary skill in the art that various changes in form and details may be made therein without departing from the spirit and scope of the present invention as defined by the following claims.

1. A method of forming a memory device, the method comprising:
forming an insulating layer on a substrate;
forming a first electrode through at least a portion of the insulating layer;
forming a memory storage element on the first electrode, wherein the first electrode is between the memory storage element and the substrate;
forming a second electrode on the memory storage element, wherein the memory storage element is between the first and second electrodes;
after forming the memory storage element and after forming the second electrode, forming insulating spacers on sidewalls of the memory storage element; and
after forming the insulating spacers, forming an interconnection line on the second electrode, on the insulating spacers, and on the insulating layer beyond the insulating spacers.

2. A method according to claim 1 further comprising:
before forming the insulating layer, forming a transistor on the substrate wherein the bottom electrode is electrically connected in series between the memory storage element and an electrode of the transistor.

3. A method according to claim 1 wherein forming the memory storage element and forming the second electrode comprise,
forming a memory storage element layer on the substrate,
forming a second electrode layer on the memory storage element layer, and
after forming the memory storage element layer and after forming the second electrode layer, patterning the second electrode layer to provide the second electrode and patterning the memory storage element layer to provide the memory storage element.

4. A method according to claim 1 wherein the memory storage element includes a phase change layer having a resistance that changes in response to changes in a phase of the phase change layer.

5. A method according to claim 1 wherein the memory storage element comprises a magnetic tunnel junction (MTJ) structure layer having a resistance that changes in response to changes in a direction of magnetic spins of a magnetic layer of the magnetic tunnel junction structure.

6. A method according to claim 1 wherein forming the insulating spacers comprises,
forming a second insulating layer on the second electrode, on sidewalls of the second electrode, on sidewalls of the memory storage element, and on the first insulating layer,
dry etching the second insulating layer to form the insulating spacers on the sidewalls of the memory storage element and to expose a surface of the second electrode opposite the substrate.

7. A method according to claim 6 wherein forming the second insulating layer comprises forming a silicon oxide layer using a plasma enhanced tetraethylorthosilicate silicon oxide deposition.

8. A method according to claim 1 wherein the insulating spacers comprises silicon oxide spacers.

9. A method according to claim 1 wherein forming the insulating spacers comprises,
forming a second insulating layer on the second electrode, on sidewalls of the second electrode, on sidewalls of the memory storage element, and on the first insulating layer,
after forming the second insulating layer, dry etching the second insulating layer to form first insulating spacers on the sidewalls of the memory storage element and to expose a surface of the second electrode opposite the substrate,
after dry etching the second insulating layer, forming a third insulating layer on the first spacers, on the second electrode, and on the first insulating layer,
after forming the third insulating layer, dry etching the third insulating layer to form second insulating spacers on the first insulating spacers and to expose a surface of the second electrode opposite the substrate.

10. A method according to claim 1 wherein forming the memory storage element includes forming the memory storage element on portions of the insulating layer surrounding the first electrode.

11. A method according to claim 1 wherein sidewalls of the memory storage element are aligned with sidewalls of the second electrode.

12. A method according to claim 1 wherein portions of the insulating layer beyond the insulating spacers are exposed after forming the insulating spacers.

13. A method according to claim 1 wherein forming interconnection line comprises forming the interconnection line directly on a surface of the second electrode opposite the substrate.

14. A method according to claim 1 wherein the memory storage element comprises resistive memory element that provides different electrical resistances to represent different data values stored therein.

15. A memory device comprising:
an insulating layer on a substrate;
a first electrode through at least a portion of the insulating layer;
a memory storage element on the first electrode, wherein the first electrode is between the memory storage element and the substrate;
a second electrode on the memory storage element, wherein the memory storage element is between the first and second electrodes;
insulating spacers on sidewalls of the memory storage element; and
an interconnection line on the second electrode, on the insulating spacers, and on the insulating layer beyond the insulating spacers, wherein the insulating spacers are between the interconnection line and sidewalls of the memory storage element.

16. A memory device according to claim 15 further comprising:
a transistor on the substrate wherein the first electrode is electrically connected in series between the memory storage element and an electrode of the transistor.

17. A memory device according to claim 15 wherein the memory storage element includes a phase change layer having a resistance that changes in response to changes in a phase of the phase change layer.

18. A memory device according to claim 15 wherein the memory storage element comprises a magnetic tunnel junction (MTJ) structure layer having a resistance that changes in response to changes in a direction of magnetic spins of a magnetic layer of the magnetic tunnel junction structure.

19. A memory device according to claim 15 wherein the insulating spacers comprises silicon oxide spacers.

20. A memory device according to claim 15 wherein the memory storage element is on portions of the insulating layer surrounding the first electrode.

21. A memory device according to claim 15 wherein sidewalls of the memory storage element are aligned with sidewalls of the second electrode.

22. A memory device according to claim 15 wherein the interconnection line is directly on portions of the insulating layer beyond the insulating spacers.

23. A memory device according to claim 15 wherein the interconnection line is directly on a surface of the second electrode opposite the substrate.

24. A memory device according to claim 15 wherein the memory storage element comprises resistive memory element that provides different electrical resistances to represent different data values stored therein.

25. A memory device according to claim 15 wherein the insulating spacers are provided in a stack structure with first spacers and second spacers being stacked.
